(19) United States
(12) Patent Application Publication
(10) Pub. No.: US 2025/0048583 A1
(43) Pub. Date: Feb. 6, 2025

(54) MOUNTING DEVICE HAVING A MOUNTING PORTION CONFIGURED TO ROTATE SO AS TO PROVIDE ENHANCED ACCESS TO A COMPONENT COUPLED THERETO

(71) Applicant: PPC BROADBAND, INC., East Syracuse, NY (US)

(72) Inventor: Gilibaldo RUIZ, East Syracuse, NY (US)

(73) Assignee: PPC BROADBAND, INC., East Syracuse, NY (US)

(21) Appl. No.: 18/793,318

(22) Filed: Aug. 2, 2024

Related U.S. Application Data
(60) Provisional application No. 63/530,807, filed on Aug. 4, 2023.

(51) Int. Cl. H05K 7/18

(52) U.S. Cl. CPC H05K 7/186

(57) ABSTRACT

A telecommunication component mounting device configured to selectively position a telecommunication component in an installed position and in an increased access position to provide enhanced access to the component, includes: a first mounting portion configured to attach a telecommunication component to an enclosure; and a second mounting portion configured to attach the component to the enclosure. The first mounting portion comprises a moving portion that is configured to engage the enclosure to limit pivoting movement of the component in a direction away from the enclosure in an increased access position, and to secure the component in an installed position; and the moving portion is configured to cooperate with the enclosure to retain the component in the increased access position so as to provide enhanced access to the component for connection of wires and/or cables to the component in the increased access position.

### CROSS-REFERENCE TO RELATED APPLICATION

This application claims the benefit of U.S. Provisional Application No. 63/530,807 filed Aug. 4, 2023, which is currently pending, the disclosure of which is hereby incorporated by reference herein in its entirety.

### BACKGROUND

The present disclosure relates generally to telecommunications enclosures and, in particular, to a telecommunications enclosure having a telecommunication component mounting bracket that holds the component in a position that facilitates installation of wires and cables to the component.

Components such as, for example, ethernet routers are often housed in an enclosure on a telephone or other service pole to protect the device from the weather and other elements. In some situations, it may be desirable to provide an enclosure and component mounting hardware for housing a component such as, for example, an ethernet router that holds the component in an installation position and holds the component in an installed position.

### SUMMARY

The present disclosure provides a much needed telecommunication component mounting device for mounting a telecommunication component in an enclosure, where the mounting device can hold the component in an installation position and hold the component in an installed position.

Embodiments provide an axial mounting bracket that has an upper bracket that is fixed to a first end (for example, the top) of the component, and a plate attached to the upper bracket at an axis. The plate rotates about the axis. The plate has a slot that is offset from the axis. A pin that is fixed to the enclosure extends through the slot. As the plate is rotated about the axis, the pin engages the slot and prevents the component from moving. A lower bracket attaches a second end (for example, a bottom end) of the component to the enclosure such that the second end of the component does not move (other than pivoting) relative to the enclosure. The plate is also structurally configured to engage a portion of the enclosure to hold the component in an installation position in which the component is pivoted such that the top of the component is separated from a back wall of the enclosure. This installation position facilitates connection of wires and/or cables to the component and permits the enclosure to be smaller since access to the wires and/or cables is not necessary with the component in the installed position.

While the above embodiment was described with reference to an upper bracket and a lower bracket, in other embodiments these brackets are mounted in different locations. For example, in some embodiments, the upper bracket is mounted to a bottom of the component and the lower bracket is mounted to a top of the component. In some embodiments, the upper bracket is mounted to one side of the component and the lower bracket is mounted to a different side of the component.

Embodiments provide a telecommunication component mounting device configured to selectively position a telecommunication component in an installed position and in an increased access position to provide enhanced access to the telecommunication component, including: an enclosure that may be configured to receive a telecommunications component; a first mounting portion that may be structurally configured to attach a first portion of a telecommunication component to the enclosure; and a second mounting portion that may be structurally configured to attach a second portion of the telecommunication component to the enclosure. The first mounting portion may comprise an engaging portion that may be structurally configured to be fixed to the enclosure; the first mounting portion may comprise a moving portion that may be structurally configured to engage the engaging portion to secure the telecommunication component in an installed position; the moving portion may be structurally configured to rotate about an axis; the first mounting portion may comprise a first connection portion that may be structurally configured to be fixed to the telecommunication component; the first connection portion may comprise a moving portion connection portion that may be structurally configured to be rotatingly connected to the moving portion; the engaging portion may comprise a pin; the moving portion may comprise a retaining portion that may be structurally configured to engage the engaging portion such that the engaging portion moves within the retaining portion; the moving portion may be structurally configured to engage a stop portion of the enclosure to limit pivoting movement of the telecommunication component in a direction away from the enclosure; the second mounting portion may comprise an enclosure attachment portion that may be structurally configured to be fixed to the enclosure; the second mounting portion may comprise a component attachment portion that may be structurally configured to be fixed to the telecommunication component; the component attachment portion may be structurally configured to pivot relative to the enclosure attachment portion such that the telecommunication component may be configured to pivot relative to the enclosure; and the moving portion may be structurally configured to cooperate with the stop portion of the enclosure to retain the telecommunication component in an increased access position so as to provide enhanced access to the telecommunication component for connection of wires and/or cables to the telecommunication component in the increased access position.

In embodiments, the first connection portion may be structurally configured to attach to the moving portion such that the moving portion rotates relative to the first connection portion.

In embodiments, the first connection portion may comprise a component connection portion that may be structurally configured to be fixed to the telecommunication component.

In embodiments, the component connection portion may be structurally configured to be fixed to the moving portion connection portion.

In embodiments, the axis may be structurally configured to be fixed relative to the moving portion connection portion.

In embodiments, the moving portion may be a plate.

In embodiments, the retaining portion may be a slot.

In embodiments, the first connection portion may be a component mount.

In embodiments, the telecommunication component mounting device further comprises a biasing connection, and the biasing connection may be structurally configured to connect the moving portion to the first connection portion.

In embodiments, the biasing connection may comprise a spring.

In embodiments, the telecommunication component mounting device further comprises a friction connection, and the friction connection may be structurally configured to connect the moving portion to the first connection portion.

In embodiments, the friction connection may comprise a wave washer.

Embodiments provide a telecommunication component mounting device configured to selectively position a telecommunication component in an installed position and in an increased access position to provide enhanced access to the telecommunication component, including: a first mounting portion that may be structurally configured to attach a telecommunication component to an enclosure; and a second mounting portion that may be structurally configured to attach the telecommunication component to the enclosure. The first mounting portion may comprise a moving portion that may be structurally configured to engage an engaging portion on the enclosure to secure the telecommunication component in an installed position; the moving portion may be structurally configured to rotate about an axis; the moving portion may be structurally configured to engage the enclosure to limit pivoting movement of the telecommunication component in a direction away from the enclosure; the second mounting portion may be structurally configured to be fixed to the enclosure and to the telecommunication component; the second mounting portion may be structurally configured to pivot such that the telecommunication component is pivotable relative to the enclosure; and the moving portion may be structurally configured to cooperate with a stop portion of the enclosure to retain the telecommunication component in an increased access position, so as to provide enhanced access to the telecommunication component for connection of wires and/or cables to the telecommunication component in the increased access position.

In embodiments, the first mounting portion may comprise the engaging portion that is structurally configured to be fixed to the enclosure.

In embodiments, the moving portion may comprise a retaining portion that may be structurally configured to engage the engaging portion such that the engaging portion moves within the retaining portion.

In embodiments, the first mounting portion may comprise a first connection portion that may be structurally configured to be fixed to the telecommunication component.

In embodiments, the second mounting portion may comprise an enclosure attachment portion that may be structurally configured to be fixed to the enclosure, and the second mounting portion may comprise a component attachment portion that may be structurally configured to be fixed to the telecommunication component.

In embodiments, the component attachment portion may be structurally configured to pivot relative to the enclosure attachment portion such that the telecommunication component is configured to pivot relative to the enclosure.

Embodiments provide a telecommunication component mounting device configured to selectively position a telecommunication component in an installed position and in an increased access position to provide enhanced access to the telecommunication component, including: a first mounting portion that may be structurally configured to attach a telecommunication component to an enclosure; and a second mounting portion that may be structurally configured to attach the telecommunication component to the enclosure. The first mounting portion may comprise a moving portion that may be structurally configured to engage the enclosure to limit pivoting movement of the telecommunication component in a direction away from the enclosure in an increased access position, and to secure the telecommunication component in an installed position; and the moving portion may be structurally configured to cooperate with the enclosure to retain the telecommunication component in the increased access position so as to provide enhanced access to the telecommunication component for connection of wires and/or cables to the telecommunication component in the increased access position.

In embodiments, the second mounting portion may be structurally configured to be fixed to the enclosure and to the telecommunication component and to pivot such that the telecommunication component is pivotable relative to the enclosure.

In embodiments, the moving portion may be structurally configured to rotate about an axis.

In embodiments, the moving portion may comprise a retaining portion that may be structurally configured to engage an engaging portion on the enclosure such that the engaging portion moves within the retaining portion.

In embodiments, the second mounting portion may comprise an enclosure attachment portion that may be structurally configured to be fixed to the enclosure, and the second mounting portion comprises a component attachment portion that may be structurally configured to be fixed to the telecommunication component.

In embodiments, the component attachment portion may be structurally configured to pivot relative to the enclosure attachment portion such that the telecommunication component is configured to pivot relative to the enclosure.

Various aspects of the system, as well as other embodiments, objects, features and advantages of this disclosure, will be apparent from the following detailed description of illustrative embodiments thereof, which is to be read in conjunction with the accompanying drawings.

### BRIEF DESCRIPTION OF THE DRAWINGS

FIG. 1 is a perspective view of an enclosure in accordance with various aspects of the disclosure.

FIG. 2 is a sectional view of the enclosure of FIG. 1.

FIG. 3 is a sectional view of the enclosure of FIG. 1.

FIG. 4 is a front sectional view of the enclosure of FIG. 1.

FIG. 5 is a partial perspective sectional view of the enclosure of FIG. 1 showing a device in an installation position.

FIG. 6 is a perspective view of a portion of a lower bracket.

FIG. 7 is a perspective sectional view of the enclosure of FIG. 1 showing the device being pivoted into the installation position.

FIG. 8 is a perspective sectional view of the enclosure of FIG. 1 showing the device in the installation position.

FIG. 9 is a perspective sectional view of the enclosure of FIG. 1 showing the device in an installed position.

FIG. 10 is a front view of the enclosure of FIG. 1 with the device in the installed position.

FIG. 11 is a perspective view of an embodiment of the upper bracket with a spring mechanism.

FIG. 12 is a perspective view of an embodiment of the upper bracket with a friction mechanism.

FIG. 13 is a perspective view of a wave washer and nut used in the embodiment of FIG. 12.

FIG. 14 is a perspective view of the upper bracket of FIG. 12 showing a rotation of a plate portion of the upper bracket.

### DETAILED DESCRIPTION OF EMBODIMENTS

Embodiments of the disclosure provide a component mounting device that is structurally configured to mount a telecommunication component in an enclosure and allow the component to pivot to an installation position and hold the component in the installation position to allow a technician use of two hands to make connections to the component, resulting in a reduction in time required for, and a simplified, installation of the component in the enclosure.

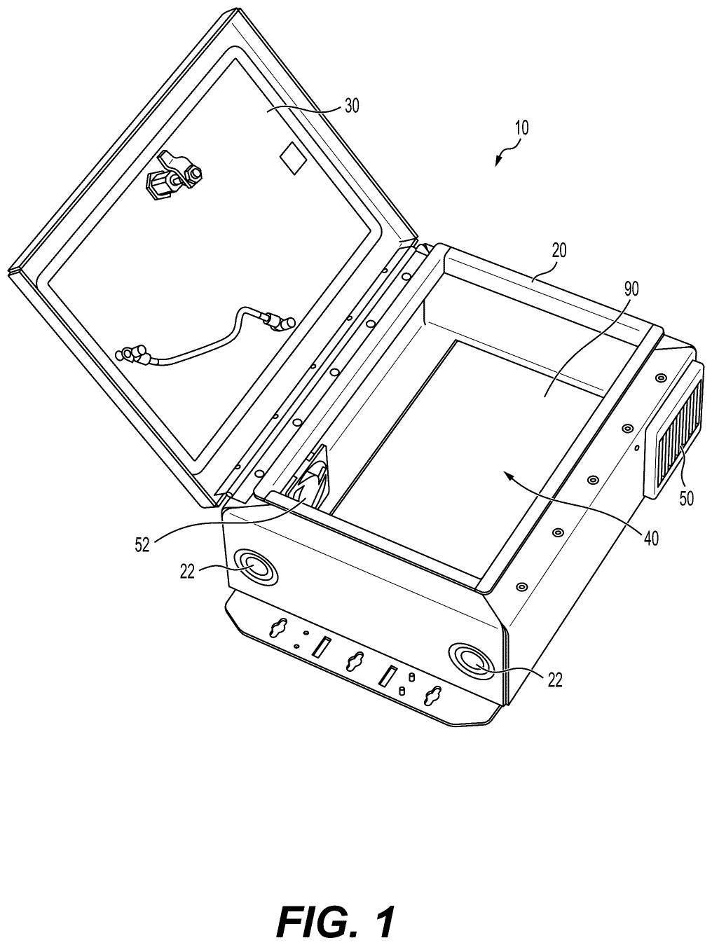

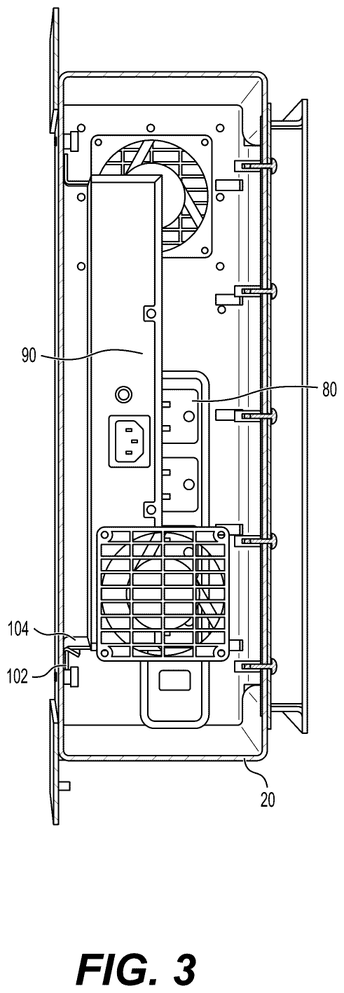

FIG. 1-4 show an example of an enclosure 10 that includes a cabinet 20 and a cover 30. The cabinet 20 has a plurality of cable entry ports 22 structurally configured to allow cables to pass from outside the cabinet 20 to an internal space 40 of the cabinet 20. A plurality of ventilation openings 50 are provided to allow ventilation air to enter and exit the cabinet 20 to provide cooling to a component, for example, a telecommunications component, 90 located in the interior space 40. Ventilation fans 52 are provided to move ventilation air through the ventilation openings 50. Also shown is a power supply 80 such as, for example, a 120 volt power strip for supplying power to the component 90. In embodiments, the component 90 is an ethernet modem. The proximity of one or more of the fans 52 and/or the power supply 80 to the telecommunications component 90 can make it difficult for a technician to install cable/wires into the telecommunications component 80.

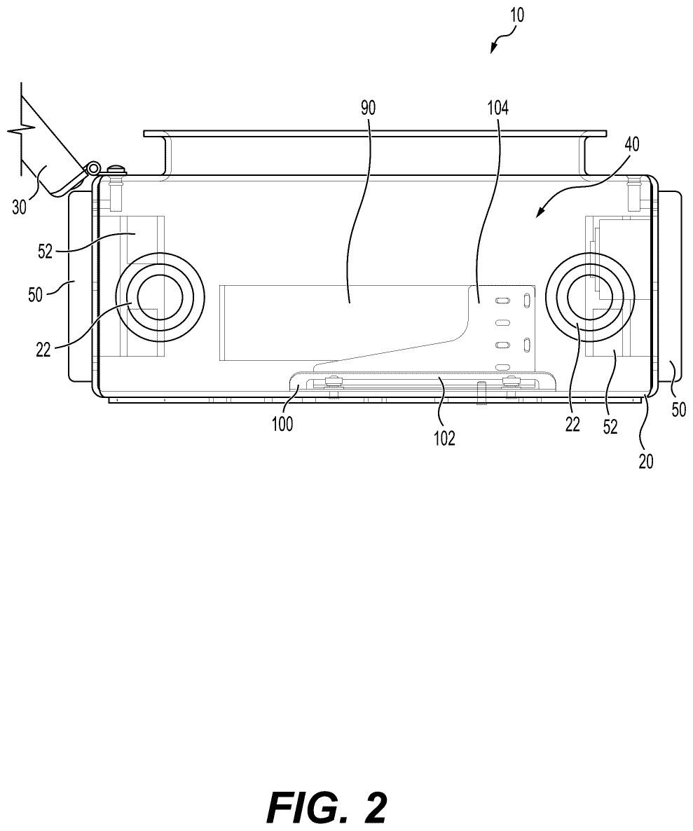

As shown in FIGS. 2-4, the component 90 is attached to the cabinet 20 by a first mounting portion (upper bracket) 200 and a second mounting portion (lower bracket) 100. In this example, the upper bracket 200 attaches the top of the component 90 to the cabinet 20, and the lower bracket 100 attaches the bottom of the component 90 to the cabinet 20. In other configurations, different sides of the component 90 are attached to the cabinet 20 by way of the upper bracket 200 and the lower bracket 100.

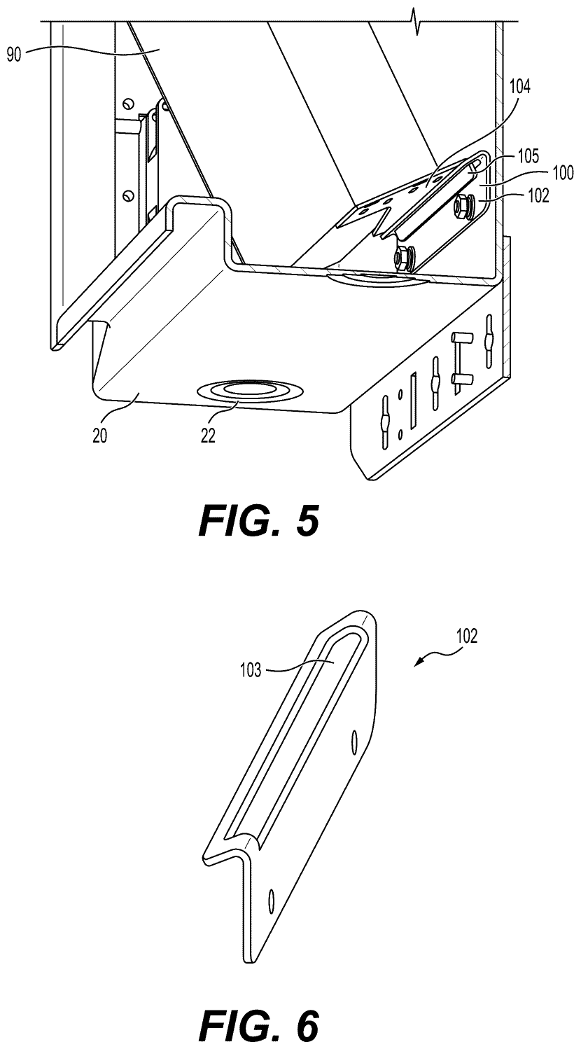

In the example shown in FIGS. 2, 5, and 6, the lower bracket 100 has an enclosure attachment portion (lower bracket enclosure tab) 102 that is structurally configured to be fixed to the cabinet 20. In this example, the lower bracket 100 has a component attachment portion (lower bracket device tab) 104 that is structurally configured to be fixed to the component 90. In this example, the lower bracket 100 is formed as one piece of plastic, metal, or other material that includes the lower bracket enclosure tab 102 and the lower bracket device tab 104. In other embodiments, the lower bracket 100 comprises multiple pieces. In embodiments, a portion 105 of the lower bracket device tab 104 is inserted into a slot 103 in the lower bracket enclosure tab 102 such that the top of the component 90 can pivot away from a back wall of the cabinet 20 while the component 90 remains attached to the cabinet 20 by the lower bracket 100.

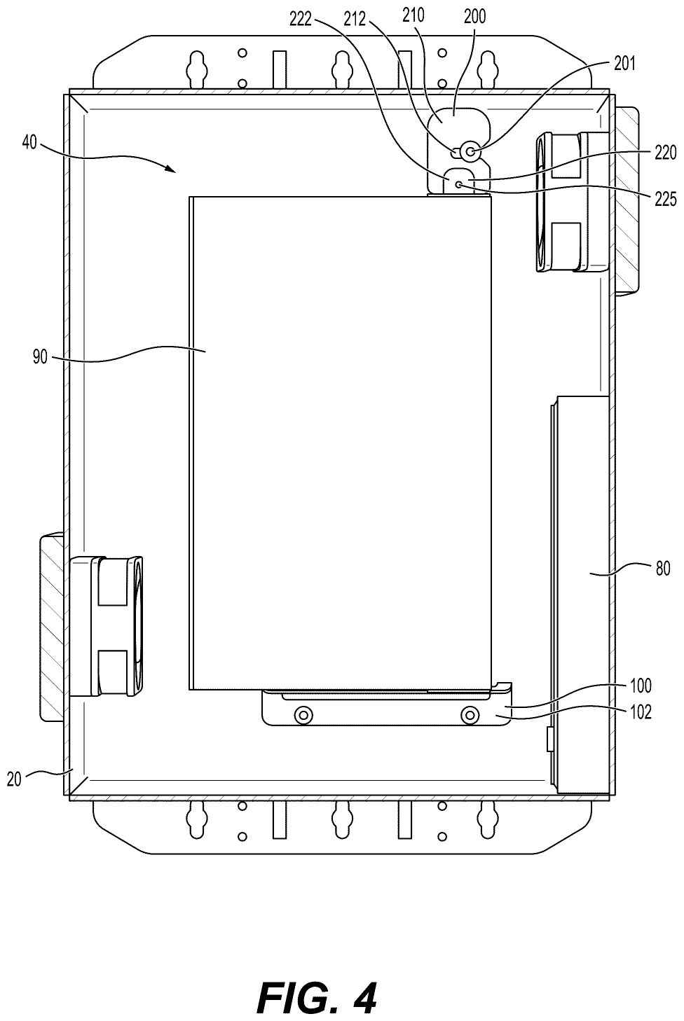

As shown in FIG. 4, the top of the component 90 is attached to the cabinet 20 by the upper bracket 200. An engaging portion, for example, a pin, 201 is fixed to a back wall of the cabinet 20 and does not move relative to the cabinet 20. The upper bracket 200 has a moving portion, for example, a plate, 210 that rotates about an axis 225. In embodiments, the axis 225 is a protrusion such as, for example, an axis pin that extends from either the plate 210 or a first connection portion, for example, a component mount, 220 that is fixed to the component 90. The plate 210 has a retaining portion, for example, an open ended slot, 212 that is structurally configured to receive the pin 201. In the example shown in FIG. 4, the component mount 220 has a component connection portion, for example, a component tab, 221 and a moving portion connection portion, for example, a plate tab, 222. In the example shown in FIG. 4, the component tab 221 is structurally configured to be fixed to the component 90. In the example shown in FIG. 4, the plate tab 222 is structurally configured to be rotatably connected to the plate 210 at the axis 225.

In embodiments, the plate 210 is pre-attached to the component mount 220 at the axis 225. A technician attaches the component tab 221 to the component 90 (with, for example, machine screws) with the plate attached to the plate tab 222, and attaches the lower bracket component tab 104 to the component 90 (with, for example, machine screws). The technician then slides the portion 105 of the lower bracket component tab 104 into the slot 103 in the lower bracket enclosure tab 102 to positionally fix the lower end of the component 90 to the cabinet 20. The technician can then pivot the component 90 such that the top end of the component 90 (with the plate 210 attached) approaches a back wall of the cabinet 20. To secure the top end of the component 90 to the back wall of the cabinet 20, the plate 210 is rotated to the position shown in FIG. 4 where the slot 212 of the plate 210 receives the pin 201. The pin 201 has a head portion 202 that has a larger dimension in at least one direction than a width of the slot 212 such that the head portion 202 prevents the plate 210 (and thus the component 90) from pivoting away from the back wall of the cabinet 20 when the pin 201 is in the slot 212 (as shown in FIG. 4).

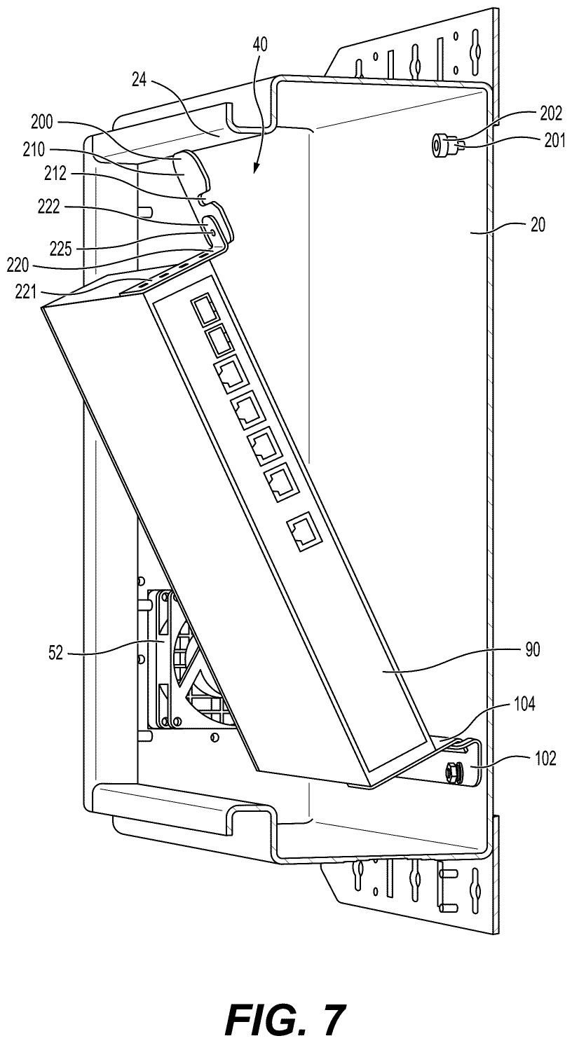

An advantage of the plate 210 being able to rotate is illustrated with reference to FIGS. 7-9. FIGS. 7-9 show three different positions (degree of pivoting) of the component 90. FIGS. 7-9 show one progression of the pivoting of the component 90 that can be utilized during installation of the component 90 in the enclosure 10.

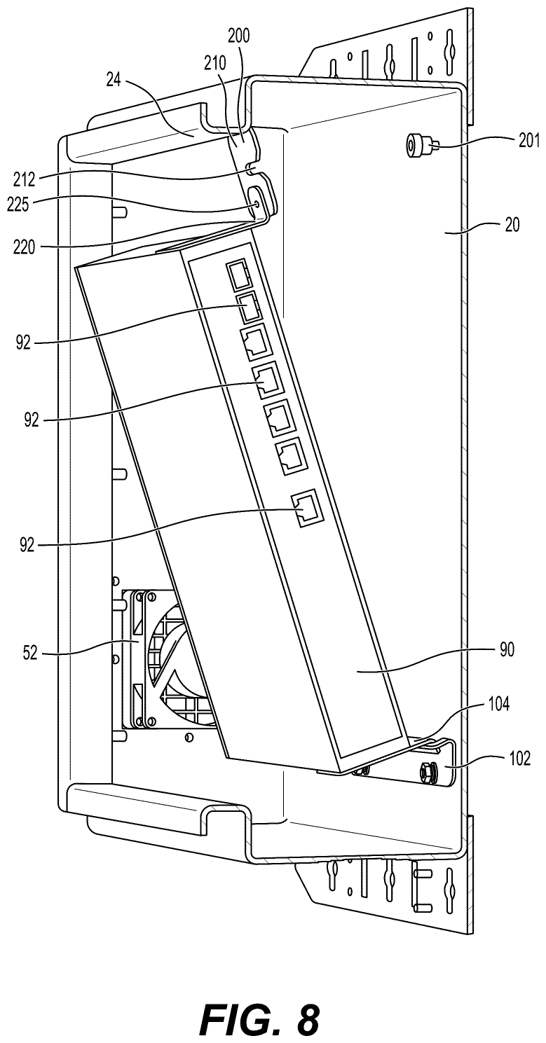

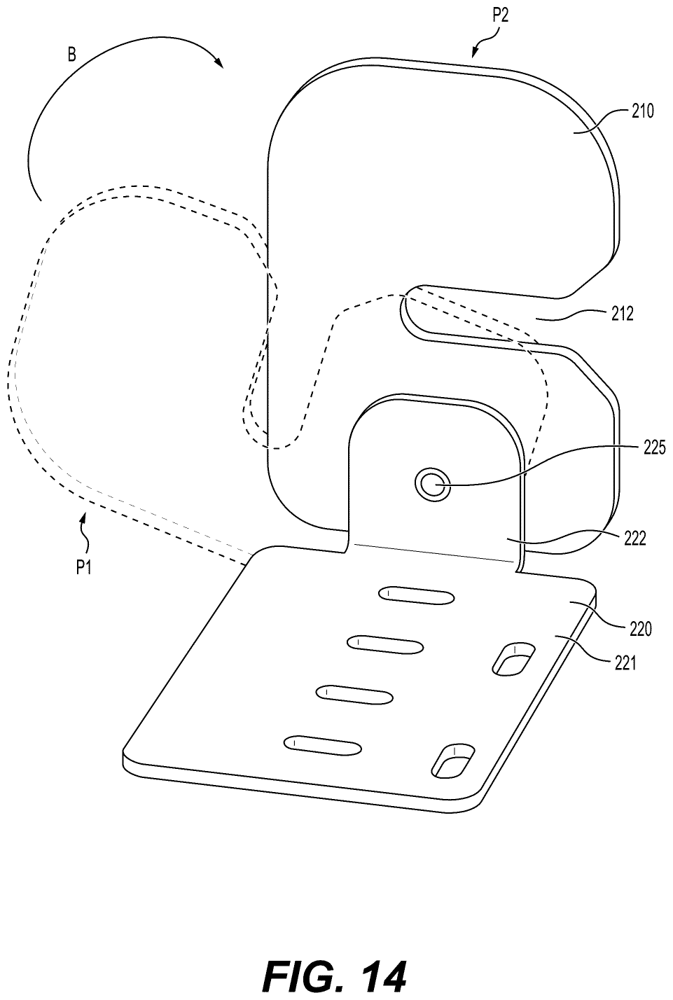

FIG. 7 shows the component 90 in a partially installed position in which the portion 105 of the lower bracket device tab 104 is inserted into the slot 103 in the lower bracket enclosure tab 102 and the component 90 is pivoted in a position where an upper portion of the plate 210 contacts an outer surface of a stop portion 24 of the cabinet 20. In order for the component 90 to pivot further toward the back wall of the cabinet 20, the plate 210 is rotated about the axis 225 (to a position P1 shown in FIG. 14) so that the plate 210 can pass beneath the stop portion 24 of the cabinet 20. After the plate 210 is moved to position P1 (or at least to a position where the plate can pass beneath the stop portion 24), the component 90 can be pivoted toward the back wall of the cabinet 20 to the position shown in FIG. 8.

FIG. 8 shows the component 90 is an installation position. In the position shown in FIG. 8, the plate 210 is in a position P2 (shown in FIG. 14) and contacts a rear side of the stop portion 24. In position P2, the plate 210 contacting the rear side of the stop portion 24 prevents the component 90 from pivoting away from the back wall of the cabinet 20. In this position, a technician does not need to hold the component 90 while the technician connects various wires and/or cables to the connection ports 92 of the component 90, freeing both hands of the technician for use to make the connections. The position P2 also facilitates the connection of the wires and/or cables by moving various connection ports 92 on the component 90 away from the back wall of the cabinet, creating more room for the technician to work and to avoid interference by one or more of the fans 52 and/or the power supply 80. If further rotation of the component 90 is desired, the plate 210 can be rotated to the P1 position shown in FIG. 14 to allow the top of the component to move further away from the back wall of the cabinet 20. However, in this position, the technician will need to hold the component to limit any further rotation since the plate 210 will no longer be contacting the stop portion 24. In one example, the distance from the back wall of the cabinet 20 to the rear of the stop portion (or flange) 24 is between 4 inches and 6 inches, more particularly, 4.75 inches. In this example of 4.75 inches, the component 90 is tilted at an angle of 20 degrees relative to the back wall of the cabinet 20. In embodiments, the component is tilted at an angle between 10 degrees and 30 degrees relative to the back wall of the cabinet. These dimensions can be different from the examples given depending on the size of the component 90 and the depth of the cabinet 20 in order for the connection ports 92 to clear one or more of the fans 52 and/or the power supply 80 to provide increase access to some or all of the connection ports 92.

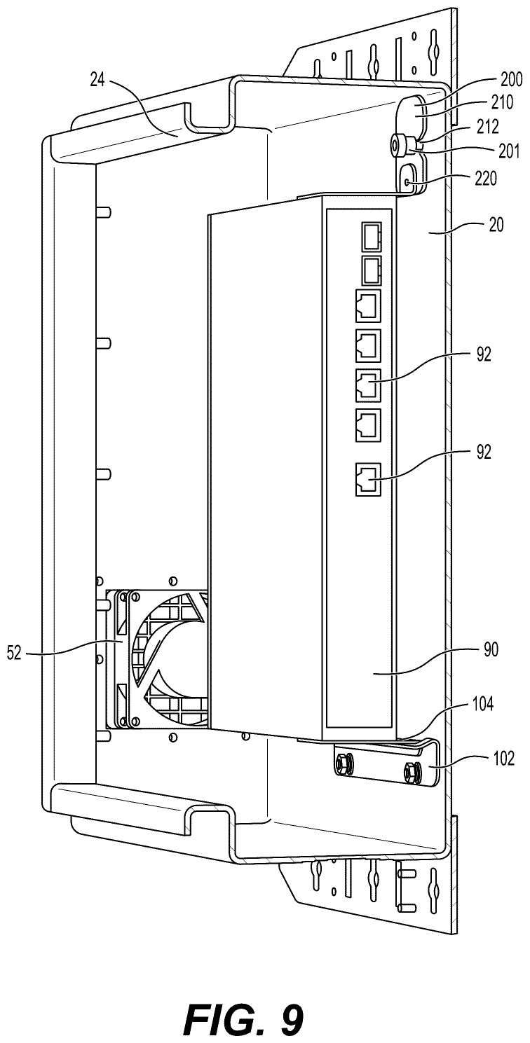

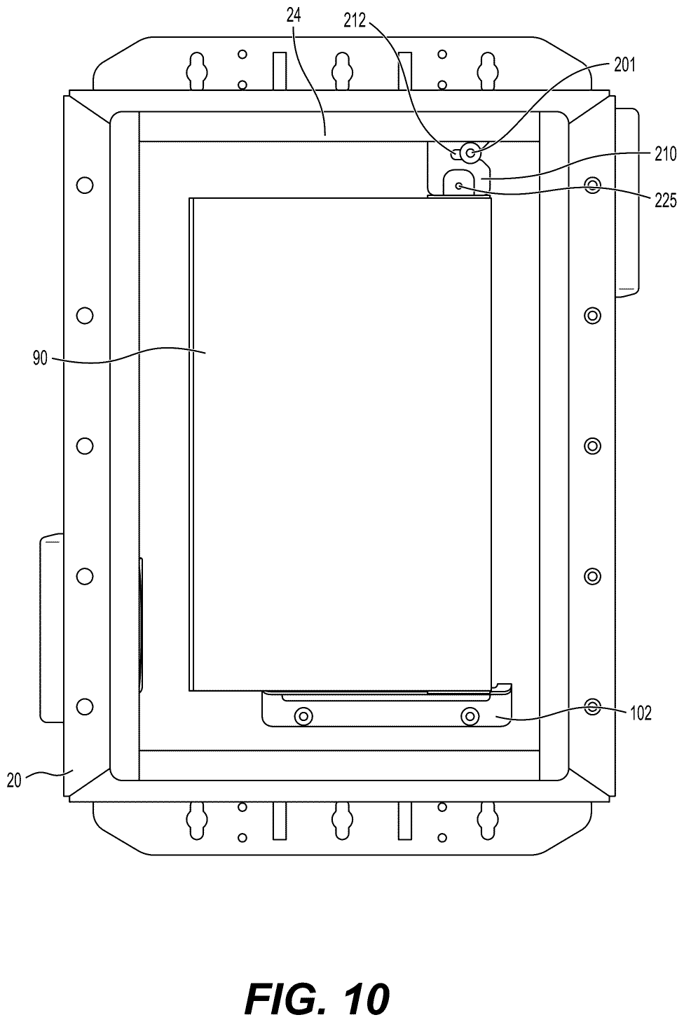

FIGS. 9 and 10 show the component 90 in the installed position where the component 90 is held to the rear wall of the component 90 by the slot 212 engaging the pin 201. In some cases, the component 90is moved to the installed position after all wires and/or cables have been attached to the component 90.

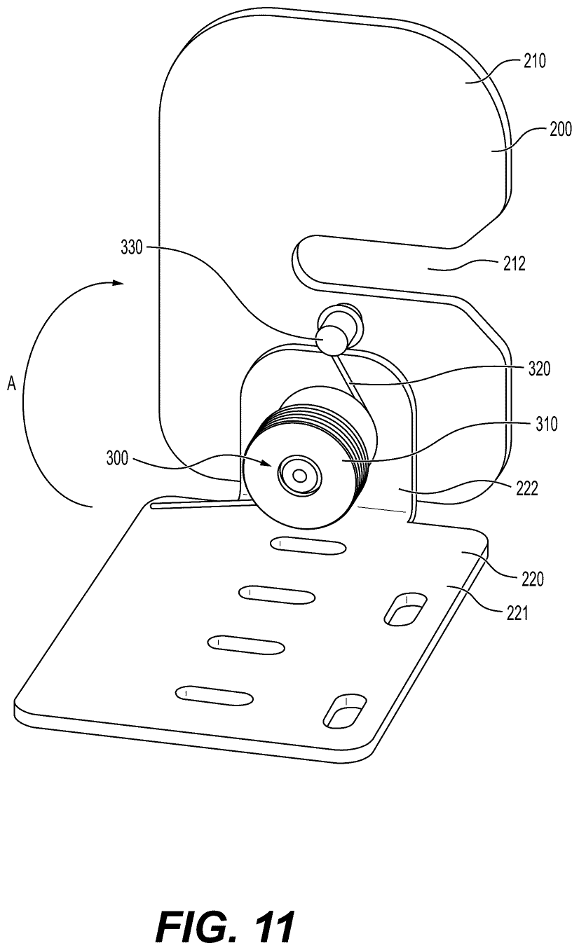

There are multiple ways to attach the plate 210 to the component mount 220. One example of an attachment mechanism is the biasing connection portion, for example, a spring mount, 300 shown in FIG. 11. In the example shown in FIG. 11, a connecting portion, for example, a nut, 310 is used to attach a biasing portion, for example, a spring, 320 to the plate tab 222 of the component mount 220. A biasing portion restraining portion (spring pin) 330 is fixed to the plate 210 and provides an anchor point for one end of the spring 320. The other end of the spring 320 is restrained by the component tab 221 of the component mount 220. The spring 320 biases the plate 210 into position P2 from position P1 (FIG. 14) to achieve two purposes. First, the biasing tends to keep the slot 212 engaged with the pin 201 when the component 90 is in the installed position. Second, the biasing tends to keep the plate 210 in contact with the rear side of the stop portion 24 of the cabinet 20 when the component 90 is in the installation position shown in FIG. 8.

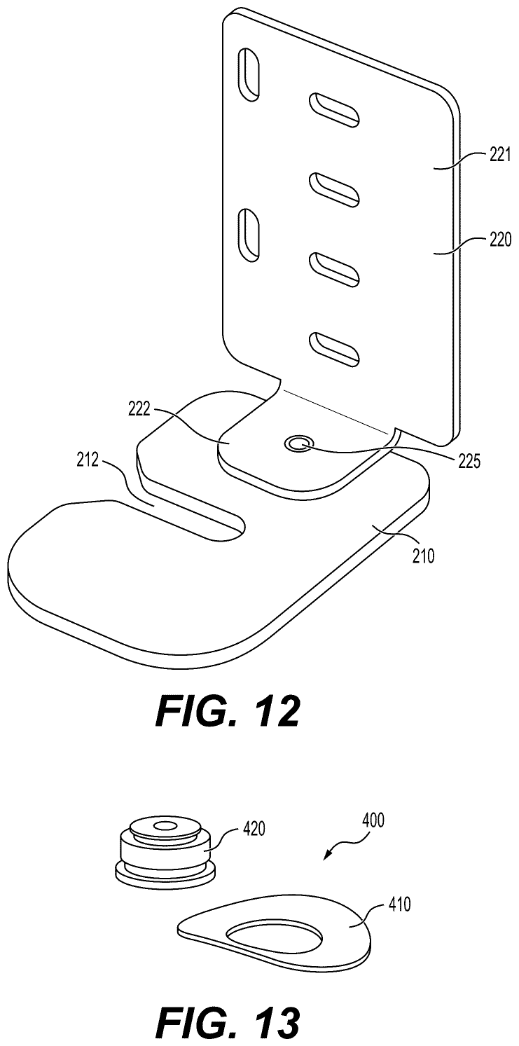

FIGS. 12 and 13 show another example of an attachment mechanism for attaching the plate 210 to the component mount 220. In this example, a friction connection portion, for example, a friction mount, 400 includes an axial biasing portion, for example, a wave washer, 410 held in place between the plate 210 and the plate tab 222 by a retaining portion, for example, a nut, 420. The wave washer 410 creates forces against the plate 210 and the plate tab 222 that increase the friction that must be overcome to move the plate 210 relative to the plate tab 222.

As described above, FIG. 14 shows positions P1 and P2 of the plate 210 relative to the component mount 220.

Although the illustrative embodiments of the present invention have been described herein with reference to the accompanying drawings, it is to be understood that the invention is not limited to those precise embodiments, and that various other changes and modifications may be effected therein by one skilled in the art without departing from the scope or spirit of the invention.

Various changes to the foregoing described and shown structures will now be evident to those skilled in the art. Accordingly, the particularly disclosed scope of the invention is set forth in the following claims.

What is claimed is:

1. A telecommunication component mounting device configured to selectively position a telecommunication component in an installed position and in an increased access position to provide enhanced access to the telecommunication component, comprising:
an enclosure configured to receive a telecommunications component;
a first mounting portion structurally configured to attach a first portion of a telecommunication component to the enclosure;
a second mounting portion structurally configured to attach a second portion of the telecommunication component to the enclosure;
wherein the first mounting portion comprises an engaging portion that is structurally configured to be fixed to the enclosure;
wherein the first mounting portion comprises a moving portion that is structurally configured to engage the engaging portion to secure the telecommunication component in an installed position
wherein the moving portion is structurally configured to rotate about an axis;
wherein the first mounting portion comprises a first connection portion that is structurally configured to be fixed to the telecommunication component;
wherein the first connection portion comprises a moving portion connection portion that is structurally configured to be rotatingly connected to the moving portion;
wherein the engaging portion comprises a pin;
wherein the moving portion comprises a retaining portion that is structurally configured to engage the engaging portion such that the engaging portion moves within the retaining portion;
wherein the moving portion is structurally configured to engage a stop portion of the enclosure to limit pivoting movement of the telecommunication component in a direction away from the enclosure;
wherein the second mounting portion comprises an enclosure attachment portion that is structurally configured to be fixed to the enclosure;
wherein the second mounting portion comprises a component attachment portion that is structurally configured to be fixed to the telecommunication component;
wherein the component attachment portion is structurally configured to pivot relative to the enclosure attachment portion such that the telecommunication component is configured to pivot relative to the enclosure; and
wherein the moving portion is structurally configured to cooperate with the stop portion of the enclosure to retain the telecommunication component in an increased access position so as to provide enhanced access to the telecommunication component for connection of wires and/or cables to the telecommunication component in the increased access position.

2. The telecommunication component mounting device of claim 1, wherein the first connection portion is structurally configured to attach to the moving portion such that the moving portion rotates relative to the first connection portion.

3. The telecommunication component mounting device of claim 1, wherein the first connection portion comprises a component connection portion that is structurally configured to be fixed to the telecommunication component.

4. The telecommunication component mounting device of claim 3, wherein the component connection portion is structurally configured to be fixed to the moving portion connection portion.

5. The telecommunication component mounting device of claim 1, wherein the axis is structurally configured to be fixed relative to the moving portion connection portion.

6. The telecommunication component mounting device of claim 1, wherein the moving portion is a plate.

7. The telecommunication component mounting device of claim 1, wherein the retaining portion is a slot.

8. The telecommunication component mounting device of claim 1, wherein the first connection portion is a component mount.

9. The telecommunication component mounting device of claim 1, further comprising a biasing connection;
wherein the biasing connection is structurally configured to connect the moving portion to the first connection portion.

10. The telecommunication component mounting device of claim 9, wherein the biasing connection comprises a spring.

11. The telecommunication component mounting device of claim 1, further comprising a friction connection;
wherein the friction connection is structurally configured to connect the moving portion to the first connection portion.

12. The telecommunication component mounting device of claim 11, wherein the friction connection comprises a wave washer.

13. A telecommunication component mounting device configured to selectively position a telecommunication component in an installed position and in an increased access position to provide enhanced access to the telecommunication component, comprising:
a first mounting portion structurally configured to attach a telecommunication component to an enclosure;
a second mounting portion structurally configured to attach the telecommunication component to the enclosure;
wherein the first mounting portion comprises a moving portion that is structurally configured to engage an engaging portion on the enclosure to secure the telecommunication component in an installed position;
wherein the moving portion is structurally configured to rotate about an axis;
wherein the moving portion is structurally configured to engage the enclosure to limit pivoting movement of the telecommunication component in a direction away from the enclosure;
wherein the second mounting portion is structurally configured to be fixed to the enclosure and to the telecommunication component;
wherein the second mounting portion is structurally configured to pivot such that the telecommunication component is pivotable relative to the enclosure; and
wherein the moving portion is structurally configured to cooperate with a stop portion of the enclosure to retain the telecommunication component in an increased access position, so as to provide enhanced access to the telecommunication component for connection of wires and/or cables to the telecommunication component in the increased access position.

14. The telecommunication component mounting device of claim 13, wherein the first mounting portion comprises the engaging portion that is structurally configured to be fixed to the enclosure.

15. The telecommunication component mounting device of claim 14, wherein the moving portion comprises a retaining portion that is structurally configured to engage the engaging portion such that the engaging portion moves within the retaining portion.

16. The telecommunication component mounting device of claim 13, wherein the first mounting portion comprises a first connection portion that is structurally configured to be fixed to the telecommunication component.

17. The telecommunication component mounting device of claim 13, wherein the second mounting portion comprises an enclosure attachment portion that is structurally configured to be fixed to the enclosure, and the second mounting portion comprises a component attachment portion that is structurally configured to be fixed to the telecommunication component.

18. The telecommunication component mounting device of claim 17, wherein the component attachment portion is structurally configured to pivot relative to the enclosure attachment portion such that the telecommunication component is configured to pivot relative to the enclosure.

19. A telecommunication component mounting device configured to selectively position a telecommunication component in an installed position and in an increased access position to provide enhanced access to the telecommunication component, comprising:
first mounting portion structurally configured to attach a telecommunication component to an enclosure;
a second mounting portion structurally configured to attach the telecommunication component to the enclosure;
wherein the first mounting portion comprises a moving portion that is structurally configured to engage the enclosure to limit pivoting movement of the telecommunication component in a direction away from the enclosure in an increased access position, and to secure the telecommunication component in an installed position; and
wherein the moving portion is structurally configured to cooperate with the enclosure to retain the telecommunication component in the increased access position so as to provide enhanced access to the telecommunication component for connection of wires and/or cables to the telecommunication component in the increased access position.

20. The telecommunication component mounting device of claim 19, wherein the second mounting portion is structurally configured to be fixed to the enclosure and to the telecommunication component and to pivot such that the telecommunication component is pivotable relative to the enclosure.

21. The telecommunication component mounting device of claim 19, wherein the moving portion is structurally configured to rotate about an axis.

22. The telecommunication component mounting device of claim 19, wherein the moving portion comprises a retaining portion that is structurally configured to engage an engaging portion on the enclosure such that the engaging portion moves within the retaining portion.

23. The telecommunication component mounting device of claim 19, wherein the second mounting portion comprises an enclosure attachment portion that is structurally configured to be fixed to the enclosure, and the second mounting portion comprises a component attachment portion that is structurally configured to be fixed to the telecommunication component.

24. The telecommunication component mounting device of claim 23, wherein the component attachment portion is structurally configured to pivot relative to the enclosure attachment portion such that the telecommunication component is configured to pivot relative to the enclosure.
